(19) United States
(12) Patent Application Publication
(10) Pub. No.: US 2010/0193239 A1
(43) Pub. Date: Aug. 5, 2010

(54) Solid Circuitry Pre-wired Electrical Safety Box

(76) Inventor: John Lee Carroll, Dalhart, TX (US)

Correspondence Address: John Lee Carroll, 1004 E. 10th, Dalhart, TX, 79022, US

(21) Appl. No.: 12/363,750

(22) Filed: Jan. 31, 2009

(51) Int. Cl. H05K 5/00

(52) U.S. Cl. 174/520

(57) ABSTRACT

A safety box to provide an electrical connection may include a main housing which may include a circuit panel having a terminal to accept an end of an electrical wire, an electrical device to connect to the circuit panel and which the connection between the circuit panel and the electrical device may be covered by nonconductive protective sleeve and a detachable auxiliary housing for connecting an electric wire to the terminal of the main housing.

### PRIORITY

The present invention claims priority under 35 USC section 119 based upon a provisional application with a Ser. No. 61/062,096 which was filed on Jan. 31, 2008.

### FIELD OF THE INVENTION

The present invention relates to electric outlet boxes and more particularly to an electric outlet box which may include a main electric box and an auxiliary electric box.

### BACKGROUND OF THE INVENTION

While most people appreciate the advantages of electric power especially in the home, fewer people realize the inherent danger of electric power. The common household voltage is sufficient to maim or kill an adult human. For example, the US Consumer Product Safety Commission has shown that on the average, they are far over 400 electrocutions in the United States per year. Electrocutions from wiring hazards which may include damaged or exposed wiring and household wiring together totaled approximately 20% of the 400 electrocutions per year. Furthermore, electrical hazards are listed as the cause of approximately 4000 injuries per year.

Electricity is the cause of over 140,000 fires each year which result in 400 deaths, 4000 injuries and $1.6 billion in property damage. It is estimated that the total economic loss due to electrical hazards is estimated to exceed 4 billion annually. The National Safety Council has indicated that the electrical hazards cost nearly 1 workplace fatality every day. Injury resulting from electricity ranks sixth among all causes of occupational industry in United States.

Before the installation of ground fault circuit interrupters, which includes a de-energize circuit when they detect the ground fault, nearly 800 people died annually from household electrocutions. Currently, fewer than 200 people die annually from household electrocutions.

Cords and plugs accounted for the larger share of home structure fire civilian deaths involving electrical distribution or lighting equipment.

### SUMMARY

A safety box to provide an electrical connection may include a main housing which may include a circuit panel having a terminal to accept an end of an electrical wire, an electrical device to connect to the circuit panel and which the connection between the circuit panel and the electrical device may be covered by nonconductive protective sleeve and a detachable auxiliary housing for connecting an electric wire to the terminal of the main housing.

The electrical device may be a plug, and the electrical device may be a switch.

The main housing may be clear, and the detachable auxiliary housing may be clear.

The terminal may be color-coded, and the auxiliary detachable housing may include a knockout.

The auxiliary detachable housing may include a fastening device to fasten to the main housing, and the main housing may include an aperture formed in the top surface of the main housing to cooperate with an aperture formed in the bottom surface of the auxiliary detachable housing.

The safety box may include a temporary detachable cover to cover the front of the main housing, and the plug may include a hinge tab.

The hinge tab may be locked by a tab locking device, and the circuit panel may be movable with respect to the main housing.

The circuit panel may move from front to back and from back to front.

### BRIEF DESCRIPTION OF THE DRAWINGS

The invention may be understood by reference to the following description taken in conjunction with the accompanying drawings, in which, like reference numerals identify like elements, and in which:

FIG. 1 illustrates a perspective view of the safety box of the present invention;

FIG. 2 illustrates a perspective view of the main housing of the safety box;

FIG. 3 illustrates a perspective view of the circuit panel of the main housing;

FIG. 4 illustrates a perspective view of the plug device of the main housing;

FIG. 5 illustrates a cross-sectional view of the plug device positioned within the main housing;

FIG. 6 illustrates a perspective view of a detachable cover for the main housing;

FIG. 7 illustrates a perspective view of the main housing and auxiliary detachable housing;

FIG. 8 illustrates a perspective view of the auxiliary detachable housing;

FIG. 9 illustrates a perspective view of the detachable cover for the main housing;

FIG. 10 illustrates a perspective view of the main housing of the safety box;

FIG. 11 illustrates a perspective view of the plug device to be used with the main housing;

FIG. 12 illustrates a perspective view of the circuit panel for the main housing;

FIG. 13 illustrates a perspective view of the plug device of the present invention; and

FIG. 14 illustrates a perspective view of the circuit panel of the present invention;

FIG. 15 illustrates a perspective view of the safety box of the present invention.

### DETAILED DESCRIPTION

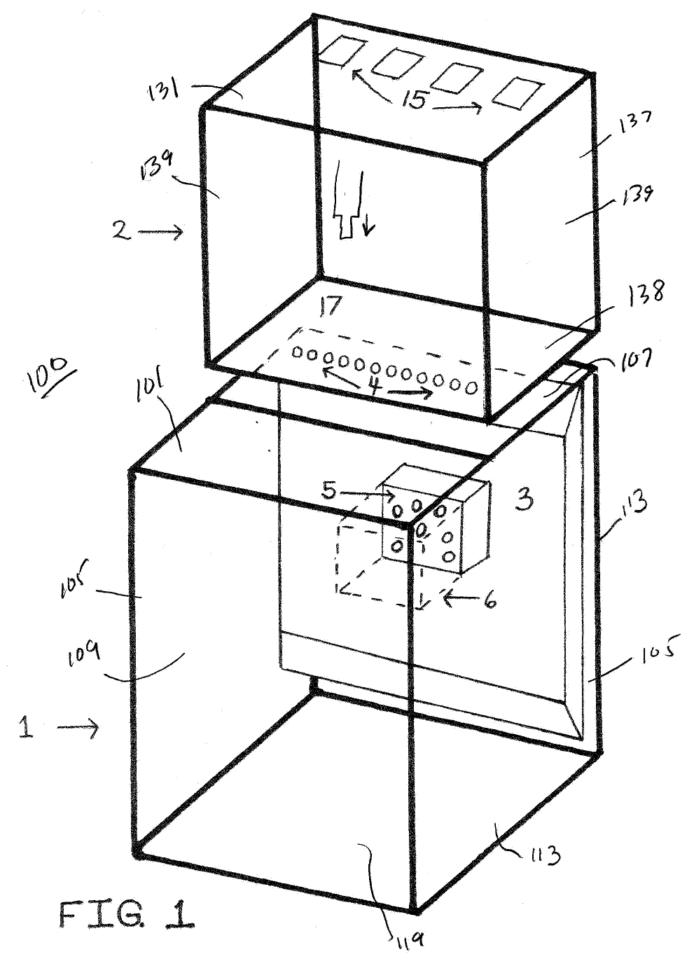

FIG. 1 illustrates a perspective view of the safety box 100 of the present invention. The safety box 100 may include a main housing 1 and a detachable ancillary housing 2. The main housing 1 may include a main top surface 101 which may extend between opposing main side surfaces 105 and may extend to the front of the main housing 1. The main top surface 101 may be truncated as it is extended rearwards in order to define a top aperture 107 which may cooperate with an auxiliary bottom aperture 109 of the detachable auxiliary housing 2. The safety box 100 may include a main back surface 113 which may extend between the main side surfaces 105 and the main bottom surface 103. A main circuit panel 103 may be connected to the main back surface 113. The safety box 100 may include a front aperture 119 which may extend between the opposing main side surfaces 105, the main back surface 113 and the main top surface 101.

The safety box 100 may include a detachable auxiliary housing 2 which may include an auxiliary top surface 131 which extends between opposing auxiliary side surfaces 139 and which may extend between the auxiliary front surface 135 and the auxiliary back surface 137. The auxiliary back surface 137 may extend between the opposing auxiliary side surfaces 139. The auxiliary front surface 135 may extend between the opposing auxiliary side surfaces 139. The auxiliary front surface 135, the auxiliary back surface 137 and the opposing auxiliary side surfaces 139 may define an auxiliary bottom aperture 138 to cooperate with the main top aperture 107. FIG. 1 illustrates that the auxiliary top surface 131 may include knockouts 15 which may include a weakened area in order that the knockouts 15 be easily removed in order for electrical wires to be inserted into the detachable auxiliary housing 2.

The circuit board 3 may include terminals 4 which may be color-coded to indicate the wire size which will be accepted by the terminal 4 and may be color-coded to indicate the voltage of the wire to be placed within terminal 4. For instance, the terminal 4 may be color-coded white in order to indicate a ground terminal for a ground wire and may include a different color code to indicate number 16 wire. The terminal 4 may be a female terminal so that a stripped wire may be inserted into the terminal 4.

The front of the circuit board 3 may include male/female connectors 5 (either a male connector, a female connector or a combination of male and female connectors) to connect to an electric device including a plug 7 (not shown in FIG. 1) or switch 8, and the male/female connectors 5 may extend outwards from the front of the circuit board 3 and may be axially enclosed by a protective sleeve 6 which may be formed from an electrical insulating material.

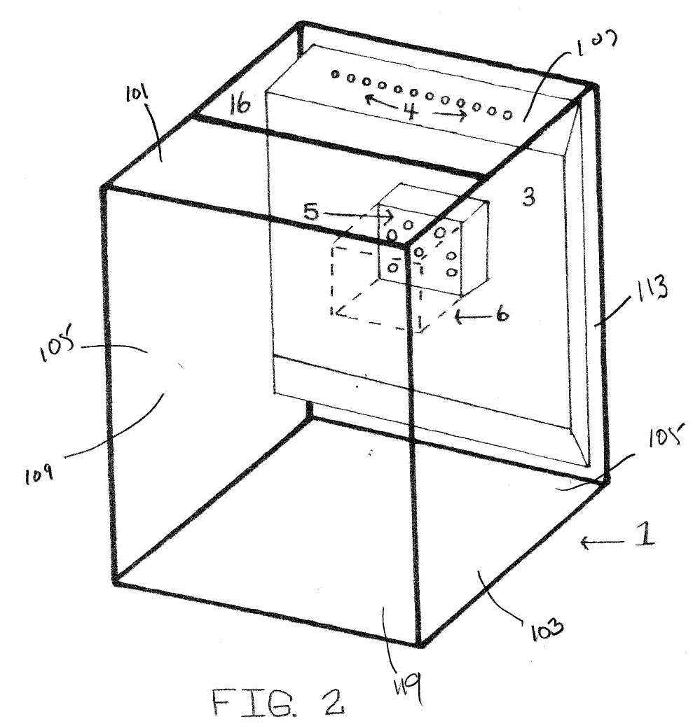

FIG. 2 illustrates a perspective view of the main housing 1 which may include the main top surface 101 which may extend between opposing main side surfaces 105 and may extend to the front of the main housing 1. The main top surface 101 may be truncated as it is extended rearwards in order to define a top aperture 107 which may cooperate with an auxiliary bottom aperture 109 of the detachable auxiliary housing 2. The main housing 1 may include a main back surface 113 which may extend between the main side surfaces 105 and the main bottom surface 103. A main circuit panel 103 may be connected to the main back surface 113. The main housing 1 may include a front aperture 119 which may extend between the opposing main side surfaces 105, the main back surface 113 and the main top surface 101.

The circuit board 3 may include terminals 4 which may be color-coded to indicate the wire size which will be accepted by the terminal 4 and may be color-coded to indicate the voltage of the wire to be placed within terminal 4. The terminal 4 may be a female terminal so that a stripped wire may be inserted into the terminal 4.

The front of the circuit board 3 may include male/female connectors 5 (either a male connector, a female connector or a combination of male and female connectors) to connect to a plug 7 (not shown in FIG. 2) or switch 8, and the male/female connectors 5 may extend outwards from the front of the circuit board 3 and may be axially enclosed by a protective sleeve 6 which may be formed from an electrical insulating material.

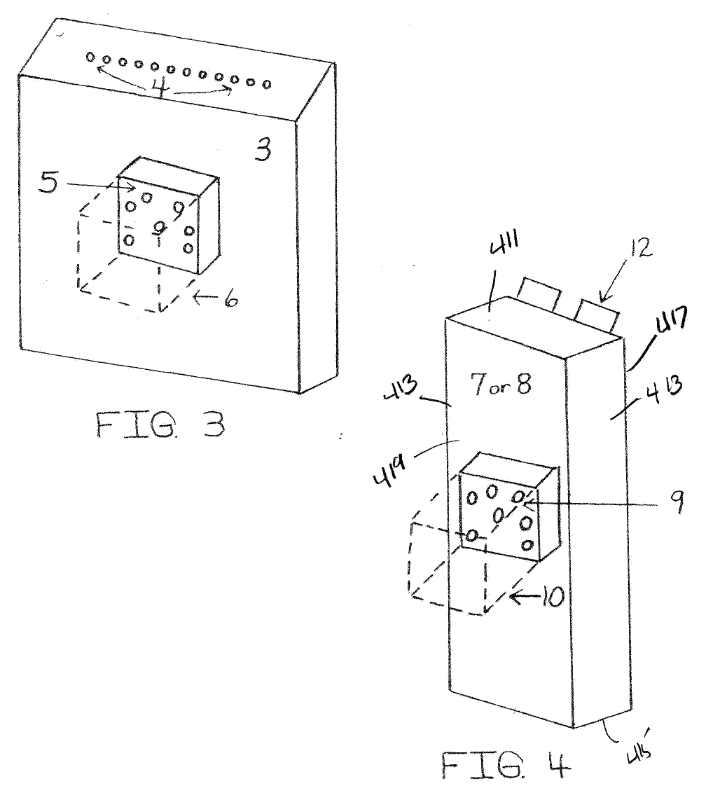

FIG. 3 illustrates that the front of the circuit board 3 may include male/female connectors 5 (either a male connector, a female connector or a combination of male and female connectors) to connect to a plug 7 (not shown in FIG. 2) or switch 8, and the male/female connectors 5 may extend outwards from the front of the circuit board 3 and may be axially enclosed by a protective sleeve 6 which may be formed from an electrical insulating material.

FIG. 4 illustrates a perspective view of the plug device 7 or alternatively a switch device 8. While the invention will be described in terms of a plug device 7, the teachings of the present invention are equally applicable to a switch device 8. The plug device 7 may include a plug top surface 411 which may extend between opposing plug side surfaces 413 and which may extend between plug back surface 417 and the plug front surface 419. The plug front surface 419 may include a female plug member (not shown) to cooperate with a male plug member. The plug side surface 413 may extend between the plug top surface 414 and the plug bottom surface 415 and may extend between the plug front surface 419 and the plug back surface 417. The plug back surface 417 may extend between the opposing plug side surfaces 413 and may extend between the plug top surface 411 and the plug bottom surface 415. The plug back surface 417 may include male/female connectors 9 which extend from the plug back surface 417 and cooperate with the male/female connectors 5 of the circuit panel 3. Additionally, a protective sleeve 10 may axially extend from the male/female connectors 9 and may be formed from electrically insulated material and cooperate with the protective sleeve 6 of the circuit panel 3 to provide a substantially continuous protective sleeve between the circuit panel 3 and the plug device 7.

FIG. 4 additionally illustrates a hinge tab 12 between the plug top surface 411 and the plug front surface 419 to maintain a spaced relationship with respect to the wall in which the plug device 7 is to be positioned. The hinge tab 12 may additionally be positioned between the plug bottom surface 415 and the plug front surface 419.

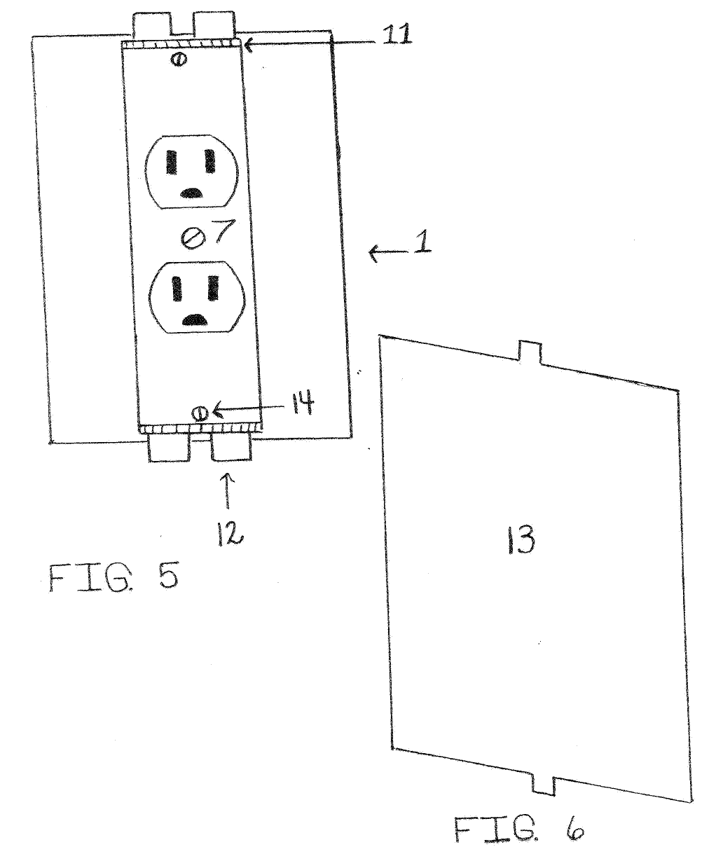

FIG. 5 illustrates a cross-sectional view of the plug device 7 which has been positioned within the main housing 1. FIG. 5 additionally illustrates a traverse travel lock hinge 11 to lock the hinge tab 12. FIG. 5 additionally illustrates a mounting screw device 14 to mount the plug device 7 to the main housing 1.

The present invention encloses substantially all of the conductive material which may be found within boxes, plugs and switches. This provides a great deal of safety for the users and owners. The present invention will provide for reduced electrocution-related deaths and injuries even when the finished covers have been removed from the boxes, plugs and switches. The boxes and switches of the present invention will be provided with preinstalled and pre-wired plugs and switches on the electric box with solid-state connections from the plugs and switches to a solid-state circuit panel positioned within the boxes. The solid state circuit panel may include electrical elements such as resistors, transistors and other circuit devices or may include only wires. The plugs and switches will be substantially fully connected and recessed in the boxes and will include a temporary and removable nonconductive cover. Accordingly, electricians which use the present invention can rough in and top out and test the same day. This provides a great savings in labor. The safety box 100 may be formed from rigid material such as metal, plastic or other appropriate material. The main housing 1 may be left, as well as right, handed and mountable with conventional fasteners. The surfaces of the circuit panel 3 may be formed from nonconductive material. The electrical terminals 4 may accept the bare portion of the wire, leaving exposed the portion of the wire which is covered by a nonconducting insulation. The present invention substantially eliminates the need for wire nuts.

The present invention eliminates substantially the open conductive material within the main housing 1 and auxiliary housing 2, resulting in additional safety. Consequently, the present invention will substantially eliminate electrocution deaths and injury when the finishing plates for the electrical boxes are missing. The present invention reduces the rough in, top-out and testing time which may be performed at the same time resulting in savings in time and money. The plugs 7 and switches 8 will be substantially active when screwed out for final trim.

The present invention will include a temporary cover which may be reinstalled after roughed in, top out and testing. This will prevent substantially foreign object and debris from entering the boxes during installation, sheetrock, tape, texturing, painting or other types of activity which could introduce foreign objects into the boxes. Keeping these foreign objects and debris out of the boxes results in saving time and money.

Substantially all the testing can be performed on the boxes before the walls, ceilings etc. are covered with sheetrock, plywood and paneling. This saves time and money because if a box is incorrectly wired, then the finished wall has to be damaged in order to repair the electrical box.

FIG. 6 illustrates the temporary detachable cover 13 which may be placed over the front aperture 119 of the main housing 1 and removed when it is desired to place the trim cover over the main housing 1. The temporary detachable cover 13 may be substantially planar and may include a rectangular shape to correspond to the edges of the main top surface 101, the main bottom surface 103 and the opposing side surfaces 105. The temporary detachable cover 13 may be formed from substantially non-conducting material.

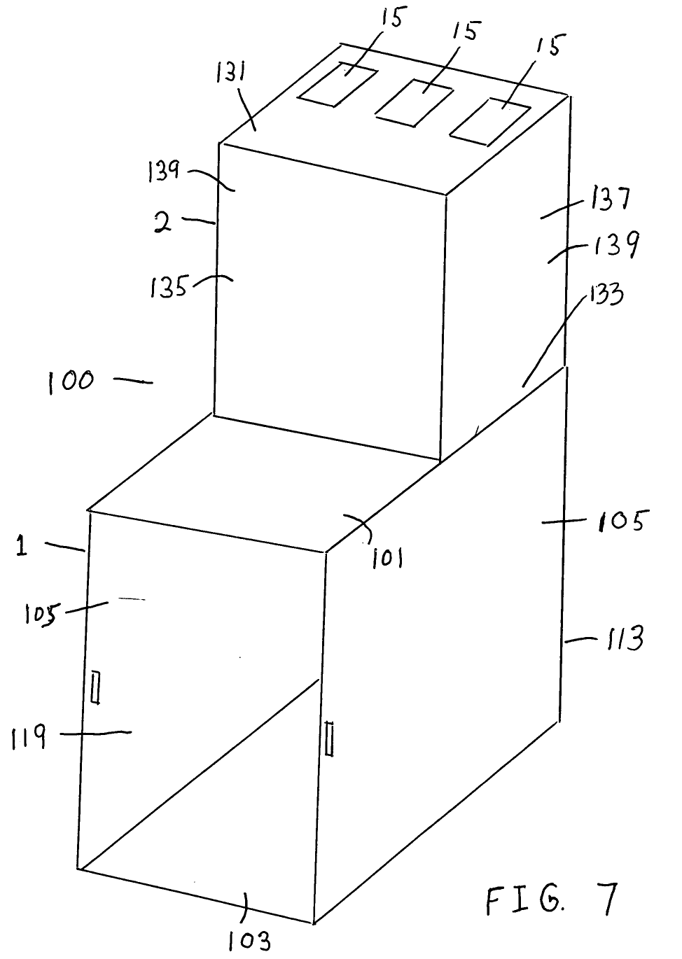

FIG. 7 illustrates a perspective view of the safety box 100 which may include a main housing 1 and the auxiliary housing 2. FIG. 7 illustrates the main top surface 101, the main bottom surface 103, the main side surface 105 and the main back surface 113. FIG. 7 additionally illustrates the front aperture 119 and the top aperture 1074 which may be in communication with the auxiliary bottom aperture. FIG. 7 illustrates the auxiliary top surface 131 which may include cutouts 15, the auxiliary bottom aperture 133, the auxiliary front surface 135, the auxiliary back surface 137 and the auxiliary side surface 139.

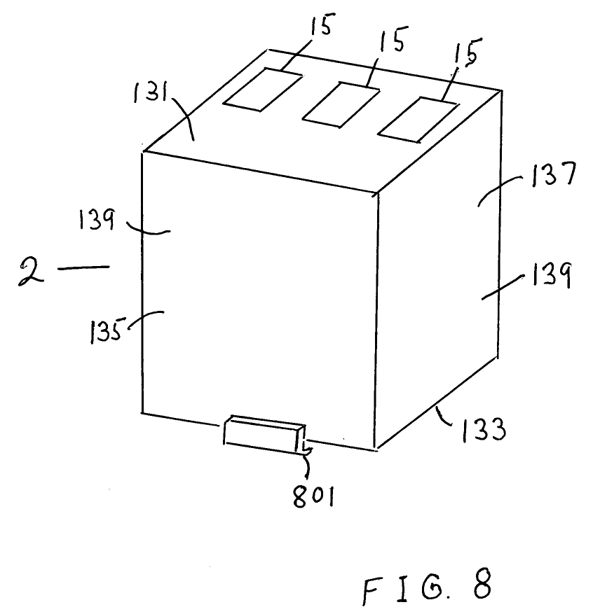

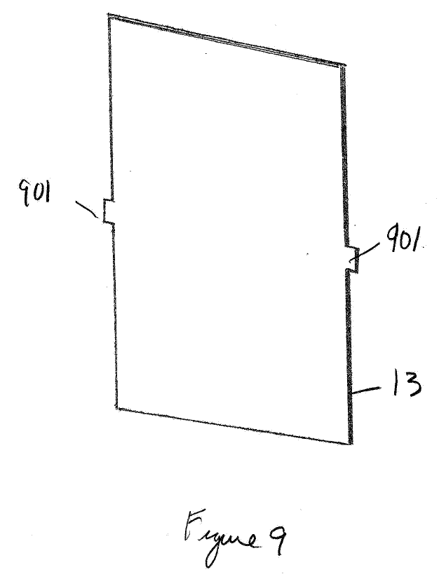

FIG. 8 illustrates the auxiliary top surface 131 which may include cutouts 15, the auxiliary bottom aperture 133, the auxiliary front surface 135, the auxiliary back surface 137 and the auxiliary side surface 139.

FIG. 8 additionally illustrates a fastening device 801 to fasten the auxiliary housing 2 to the main housing 1.

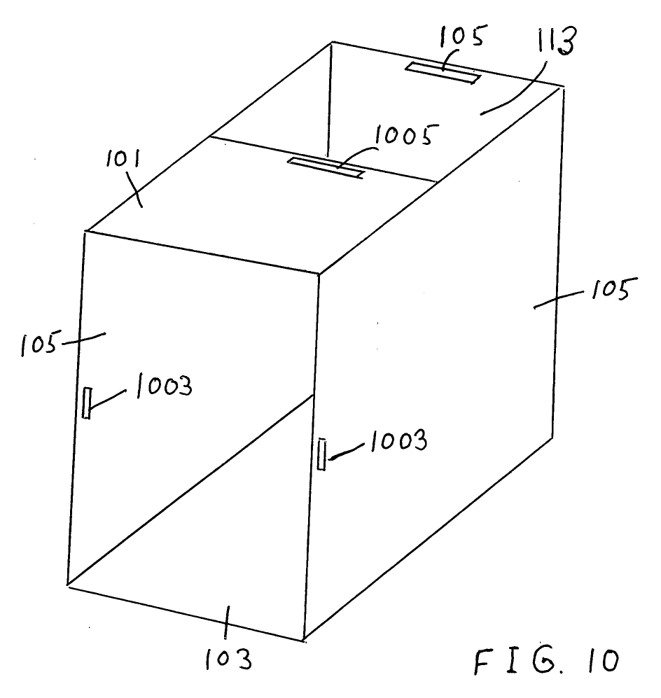

FIG. 9 illustrates the temporary detachable cover 13 which may include attachment tabs 901 for attachment to the main housing 1.

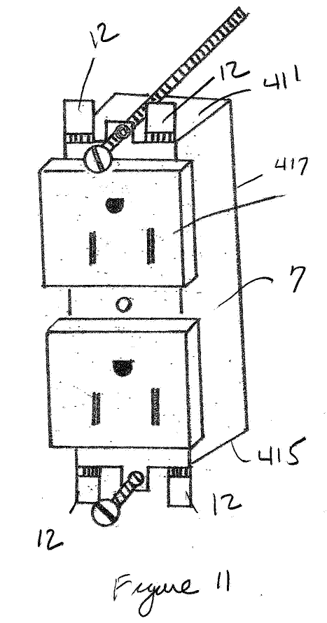

FIG. 10 illustrates a perspective view of the main housing. FIG. 10 illustrates the main top surface 101, the main bottom surface 103, the main side surface 105 and the main back surface 113. FIG. 7 additionally illustrates the front aperture 119 and the top aperture 1074.

FIG. 10 additionally illustrates an attachment aperture 1003 formed in the main side surface 103 to cooperate with the attachment tab 901 of the detachable temporary cover 113. Furthermore FIG. 10 illustrates a fastening aperture 1005 to cooperate with the fastening device 801 of the auxiliary housing 2.

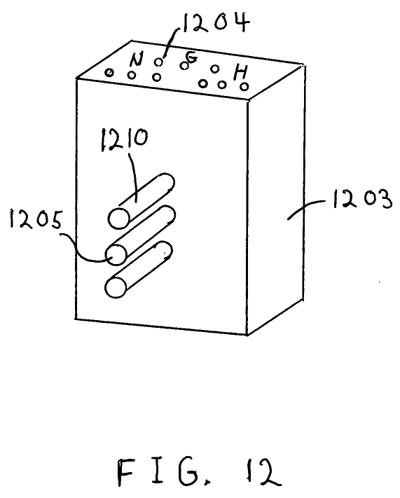

FIG. 11 illustrates a perspective view of the plug 7 which may be a switch 8 and illustrates the hinge tab 12. FIG. 11 additionally illustrates the plug top surface 411, the plug side surface 413, the plug bottom surface 415, the plug back surface 417 and the plug front surface 419.

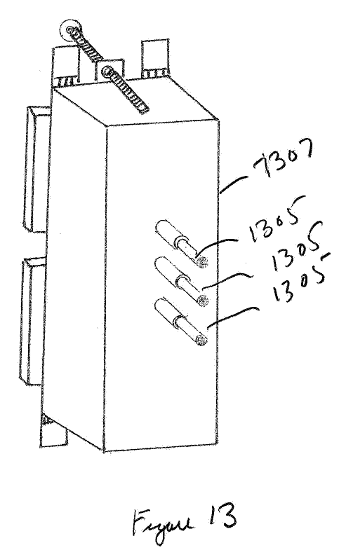

FIG. 12 illustrates a perspective view of the circuit panel 1203 and illustrates that the terminals are grouped in accordance with voltage. There are multiple terminals for the hot voltage depicted by H; there are multiple terminals for the neutral voltage depicted by N; and there are multiple terminals for the ground voltage depicted by G. The circuit panel 1203 connects the terminals of the same voltage and is connected to a single female connector 1205 which may be covered by a protective cover 1210.

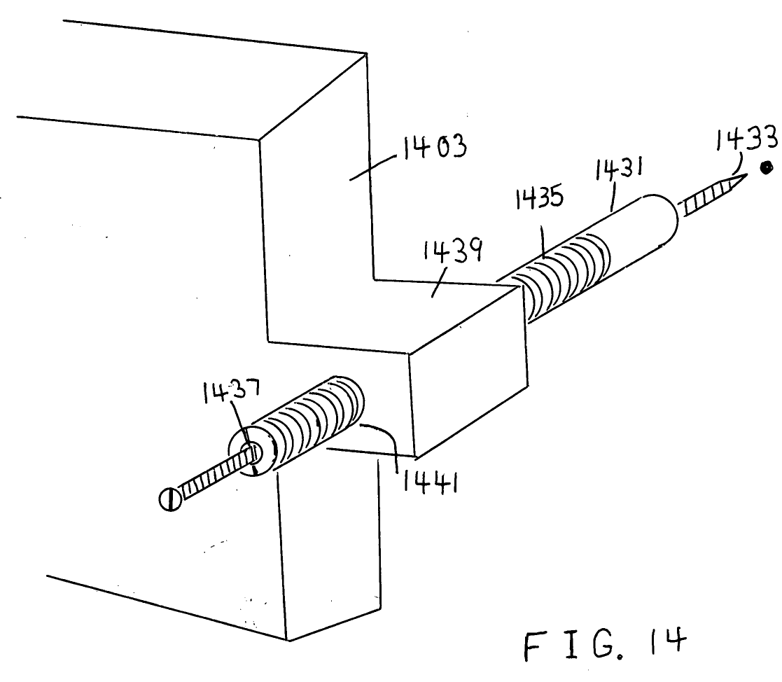

FIG. 13 illustrates a perspective view of the plug 1307 and illustrates male connectors 1305 which cooperates with the female connectors 1205. The male connectors 1305 and the female connectors 1205 may be offset so that it is substantially impossible for the user to crossconnect the proper voltage male connector 1305 with the corresponding voltage female connector 1205.

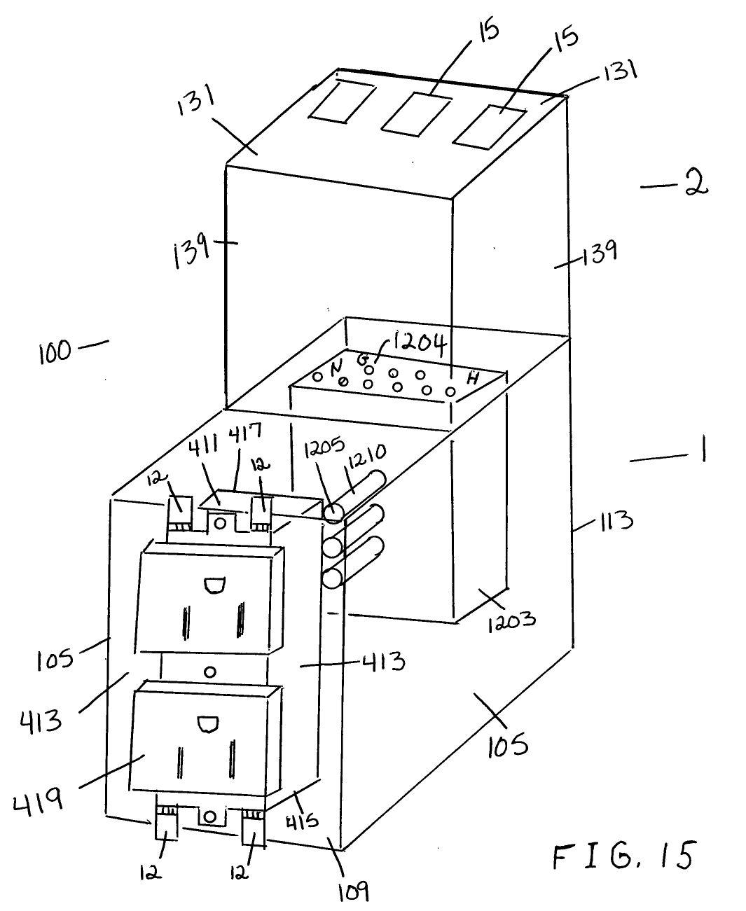

FIG. 14 illustrates a perspective view of the circuit panel 1403 which may be adjustable in position with respect to the main housing 1. The circuit panel 1303 is connected to the main housing 1 by a threaded device 1431 which includes an inner male threaded device 1433 which is threadably connected to an outer male threaded device 1435 by a central threaded aperture 1437. The outer male threaded device 1435 is connected to an arm 1439 of the circuit panel 1403 by a threaded aperture 1441. The position of the circuit panel 1403 may be adjusted by turning the outer male threaded device 1435, and the circuit panel 1403 is secured to the main housing 1 by the inner male threaded device 1433.

FIG. 15 illustrates a perspective view of the safety box 100 of the present invention. The safety box 100 may include a main housing 1 and a detachable ancillary housing 2. The main housing 1 may include a main top surface 101 which may extend between opposing main side surfaces 105 and may extend to the front of the main housing 1. The main top surface 101 may be truncated as it is extended rearwards in order to define a top aperture 107 which may cooperate with an auxiliary bottom aperture 109 of the detachable auxiliary housing 2. The safety box 100 may include a main back surface 113 which may extend between the main side surfaces 105 and the main bottom surface 103. A main circuit panel 103 may be connected to the main back surface 113. The safety box 100 may include a front aperture 119 which may extend between the opposing main side surfaces 105, the main back surface 113 and the main top surface 101.

The safety box 100 may include a detachable auxiliary housing 2 which may include an auxiliary top surface 131 which extends between opposing auxiliary side surfaces 139 and which may extend between the auxiliary front surface 135 and the auxiliary back surface 137. The auxiliary back surface 137 may extend between the opposing auxiliary side surfaces 139. The auxiliary front surface 135 may extend between the opposing auxiliary side surfaces 139. The auxiliary front surface 135, the auxiliary back surface 137 and the opposing auxiliary side surfaces 139 may define an auxiliary bottom aperture 138 to cooperate with the main top aperture 107.

FIG. 15 illustrates that the auxiliary top surface 131 may include knockouts 15 which may include a weakened area in order that the knockouts 15 be easily removed in order for electrical wires to be inserted into the detachable auxiliary housing 2.

FIG. 15 illustrates a perspective view of the plug 7 which may be a switch 8 and illustrates the hinge tab 12. FIG. 15 additionally illustrates the plug top surface 411, the plug side surface 413, the plug bottom surface 415, the plug back surface 417 and the plug front surface 419.

FIG. 12 illustrates a perspective view of the circuit panel 1203 and illustrates that the terminals are grouped in accordance with voltage. There are multiple terminals for the hot voltage depicted by H; there are multiple terminals for the neutral voltage depicted by N; and there are multiple terminals for the ground voltage depicted by G. The circuit panel 1203 connects the terminals of the same voltage and is connected to a single female connector 1205 which may be covered by a protective cover 1210.

The main housing 1 and the auxiliary housing 2 described above may be formed from clear or translucent material in order that the main housing 1 and the auxiliary housing 2 can be easily inspected by the appropriate authorities.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed.

1. A safety box to provide an electrical connection, comprising:
a main housing including: a circuit panel having a terminal to accept an end of an electrical wire;
an electrical device to connect to the circuit panel;
wherein the connection between the circuit panel and the electrical device is covered by nonconductive protective sleeve; and
a detachable auxiliary housing for connecting an electric wire to the terminal of the main housing.

2) A safety box to provide an electrical connection as in claim 1, wherein the electrical device is a plug.

3) A safety box to provide an electrical connection as in claim 1, wherein the electrical device is a switch.

4) A safety box to provide an electrical connection as in claim 1, wherein the main housing is clear.

5) A safety box to provide an electrical connection as in claim 1, wherein the detachable auxiliary housing is clear.

6) A safety box to provide an electrical connection as in claim 1, wherein the terminal is color-coded.

7) A safety box to provide an electrical connection as in claim 1, wherein the auxiliary detachable housing includes a knockout.

8) A safety box to provide an electrical connection as in claim 1, wherein the auxiliary detachable housing includes a fastening device to fasten to the main housing.

9) A safety box to provide an electrical connection as in claim 1, wherein the main housing includes a aperture formed in the top surface of the main housing to cooperate with an aperture formed in the bottom surface of the auxiliary detachable housing.

10. A safety box to provide an electrical connection as in claim 1, wherein the safety box includes a temporary detachable cover to cover the front of the main housing.

11) A safety box to provide an electrical connection as in claim 2, wherein the plug includes a hinge tab.

12) A safety box to provide an electrical connection as in claim 11, wherein the hinge tab is locked by a tab locking device.

13) A safety box to provide an electrical connection as in claim 1, wherein the circuit panel is movable with respect to the main housing.

14) A safety box to provide an electrical connection as in claim 13, wherein the circuit panel moves from front to back and from back to front.
